(19) United States
(12) Patent Application Publication
(10) Pub. No.: US 2010/0176798 A1
(43) Pub. Date: Jul. 15, 2010

(54) MAGNET SYSTEM FOR BIOSENSORS

(75) Inventor: Petrus Johannes Wilhelmus Van Lankvelt, Boekel (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/376,614

(22) PCT Filed: Jul. 10, 2007
(86) PCT No.: PCT/IB07/52749

§ 371 Date: Feb. 6, 2009

(30) Foreign Application Priority Data
Aug. 9, 2006 (EP) 06118660.7

(51) Int. Cl. G01R 33/12

(52) U.S. Cl. 324/204

(57) ABSTRACT

The invention relates to a magnet system for biosensors. To achieve a magnetic system, which can switch between attraction force and repulsion force, near the sensor surface, the magnetic system has at least one coil (1) and a ferromagnetic open ring system (3), where both magnetic pole faces are adjacent to each other over a gap (4) in which the biosensor is located, and where the coil (1) or the ferromagnetic core (2) in the coil, or an inner part of the ferromagnetic core in relation to each other are shiftable, in order to change the magnetic force direction near the biosensor surface.

The invention relates to a magnet system for biosensors.

For the conditioning biomaterial in order to reach an effective evaluation of biomaterial components, the biomaterial has to be brought into a close contact to the surface of the biosensor. Therefore an attracting force to the biomaterial must be generated. This is usually realised by magnetic beads, which will be chemically or physically bound to the biomaterial. A magnetic attraction force must be generated near the sensor surface, in order to bring the biomaterial into a close contact to the biosensor-surface.

Magnetic actuation is crucial for the operation of biosensors. Firstly, it speeds up the concentration and therefore the binding process of the magnetic particles at the sensor surface. Secondly, magnetic washing can replace the traditional wet washing step, which is more accurate and reduces the number of operating actions.

Compared to the chip dimensions, large external electro-magnets are used for actuation in order to achieve homogeneous field gradients at the sensor surface and large penetration depth over the entire sample volume. These qualities are hard to achieve with integrated actuation structures.

The used biosensors of biochips have promising properties for bio-molecular diagnostics in terms of sensitivity, specificity, integration, ease of use and costs.

Examples of such biochips are given in WO 2003054566, which describe excitation with uniform magnetic fields.

A biosensor is based on the detection of super-paramagnetic beads and may be used to simultaneously measure the concentration of a large number of different biological molecules in a solution of biomaterial.

So the sensor-surface must have a close contact to the biomaterial which can be caused, by bringing the biomaterial very close to the sensor surface with the help of the mentioned magnetic beads. The washing is used to remove the unbind and non-specific bind beads from the sensor surface for proper end-point measurement.

This can also be realised with the magnetic beads mixed and/or bind with the biomaterial, thus generating a magnetic repulsion force near the sensor surface.

Normally, a magnetic force induced by a magnet or an electromagnet is directed towards the magnet. Therefore, two magnets are needed for inducing a magnetic force toward the sensor surface, the so called sedimentation, and away from the sensor surface, the so called washing.

For this, the effected magnetic forces have to be big enough to realise this.

So it is the object of the present invention, to achieve a magnetic system with the aforesaid properties which can switch between attraction force and repulsion force near the sensor surface, wherein the magnetic forces in both directions are as high as possible, in order to increase the speed and decrease the power consumption.

An advantage of the invention is to produce very high magnetic forces in both directions, between those can be switched only by using mechanical or electromechanical means.

The stated object is achieved for a magnetic system for biosensors by characterizing features of patent claim 1.

Further embodiments of this magnetic system are characterized in the dependant claims 2-10.

The stated object is also achieved for operating a magnetic system for biosensors, by characterizing features of patent claim 11.

Further embodiments of this method are characterized in dependent claims 12 and 13.

The stated object of the invention is achieved for a magnetic system for biosensors, one coil and a ferromagnetic open ring system, where both magnetic pole faces are adjacent to each other over a gap in which the biosensor is located, and where the coil or the ferromagnetic core in the coil, or an inner part of the ferromagnetic core are shiftable in relation to each other, in order to change the magnetic force direction near the biosensor surface.

A key aspect of the invention is that the pole shoe contains a region with low magnetic susceptibility, e.g. a cup-like volume without magnetic material. This low-magnetic region can have an axially symmetric shape, as has been indicated in the examples of this invention. However, the axial symmetry is not essential. For example, the low-magnetic region can also have a slit-like shape or rectangular shape. Also, the low-magnetic region can be enclosed or open.

This invention considers a magnet which can do both. Beside a normal attraction force, this magnet is also capable of applying a repulsive force.

The at least inner part of the ferromagnetic core, which is shiftable, can have cylindrical coaxial, squared, or rectangular cross-section.

Also power consumption is a big issue in portable point-of-care applications. Therefore, it is important to maximize the force that can be generated with an electro-magnet. When the special magnet disclosed in this invention is used in combination with a normal magnet or electromagnet, the magnitude of the magnetic force can be increased substantially. It is also possible to create the same force at much lower currents compared to the situation in which only standard magnets are used.

So the essential feature of the invention is the resulting opening in the magnetic core, when the coil or the outer part of the core is shifted towards the gap. By shifting this coil back and shifting the other coil towards the gap, the direction of the magnetic force at the position of the biosensor-surface will change. This change between repulsive and attractive force can be “switched” very easily. So the modi can be quickly and easily switched between “attraction/sedimentation” and “washing”.

With other words, this causes a magnetic repulsion force near the surface in a defined near distance and in a farer distance an attraction force on the biomaterial conditioned with the magnetic beads. So it is essential to switch between the magnetic force directions by a single magnetic system, by changing the relative position between magnet and sensor surface.

In both cases inhomogeneous magnetic field lines are induced, which cause in a defined distance region an attractive force and in another distance a repulsive force. It is essential to this invention that both force directions are given by only one magnetic core.

For the advantageous use for biosensors, an embodiment of the invention discloses that the sensor is an array of several sensors. This results in a very effective sensor with a big resulting sensor-active surface.

The biosensor is adjustable in the position in the gap of the ferromagnetic open ring system.

A further embodiment of the invention is that the definable end positions of the sensor movement can be optimized by a magnetic field sensor, which can be moved simultaneously with the sensor, in order to evaluate optimal positions of the magnetic flux.

By this, the magnetic forces generated near the sensor surface can be optimized in their strength in order to generate maximum magnetic force in attraction mode as well as in repulsion mode. This causes an intense contact to the biomaterial in sensing modus, as well as an optimal repulsion in washing modus.

A further embodiment of the invention is, that the coil or the coil carrying means are shiftable along the ferromagnetic sections near the gap. This defines the effective shift of the coils in order to switch between the magnetic force directions in the gap, or at least in the region near the active biosensor-surface.

For an easy and effective movement, a further embodiment of the invention achieves the ferromagnetic open ring system with at least a cylindrical cross section along the length of the shift of the coils.

The most effective embodiment is, wherein two coils are used, so that each side of the open magnetic ring carries at least one slideable coil, wherein the two coils are coupled in the movement. So dependent on the desired magnetic force direction one coils shuts close with the pole surface of one pole, whereas the coil of the other pole is shifted forwards, so that a cylindrical cuplike cavity inside the core occurs at this side of the gap.

To change the magnetic force direction, the coil and the outer core ring, which cause the cuplike cavity will be drawn or shifted back, so that this one will shut close with this pole surface, wherein simultaneously the other coils will be shifted so that it causes a cuplike opening on the other pole surface.

In order to realise this easily, the two coils are coupled together in their movement, for example mechanically.

In order to boost the magnetic forces, further coils are arranged immotile in the ferromagnetic ring, in order to boost the magnetic forces in the gap of the open ferromagnetic ring.

Also the biosensor can be adjustable according to an optimized position in the gap, so it is an advantageous embodiment of the invention, that the biosensor is adjustable in the position in the gap of the ferromagnetic open ring system.

A last advantageous embodiment of the invention is, to achieve a magnetic field sensor, which is located near the biosensor. By this the sensor or the sensor surface can be adjusted in the optimum position of effective magnetic forces.

A further object of the invention is a method for operating a magnetic system with biosensor as described in one of the aforesaid claims, by which a sensing material or liquid is dispersed with or chemically bound to microscopic magnetic beads, and one of the ferromagnetic core, or an inner coaxial cylindrical part of the magnetic core, or one of the coil is shifted backwards, in order to generate magnetic repulsion near the sensor surfaces area to wash the surface by repulsion forces of the magnetic beads, then the other ferromagnetic core, or an inner coaxial cylindrical part of the magnetic core, or one of the coil is shifted backwards in order to generate attraction forces to the magnetic beads for sensing the bio-substrate in a very close contact to the sensor surface.

By using the aforesaid magnetic system, the method gives an effective realisation of a method for using such a system for biosensors. The aforesaid problems are solved in a technical effective way.

By switching between the two distance positions, the sensor can be switched between optimized measuring modus and optimized washing modus.

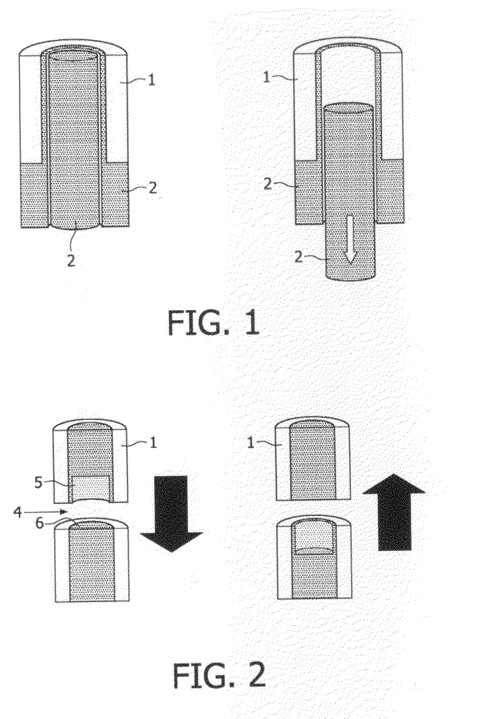

Different embodiments of the invention are shown in FIG. 1 to FIG. 4.

FIG. 1 displays an embodiment of the invention, in which is shown the detailed part of the magnetic system. Left side shows the relative position of the coil 1, in which one end of the coil, or the ferromagnetic carrier of the coil is in a position close to the pole surface of the open ferromagnetic ring. This is one defined position of desired magnetic orientation according to the biosensor, which position is not explicitly shown in this figure, but near to the upper pole surface. Right side shows another defined relative position between ferromagnetic core 2 and the coil 1. Here the ferromagnetic core seems to be shifted back so that at the upper pole surface is caused a cylindrical cuplike opening. In difference to the relative position shown at the left side, the orientation of effective magnetic force is switched into the other direction. This for an equal defined distance between the pole surface and the not explicitly shown biosensor.

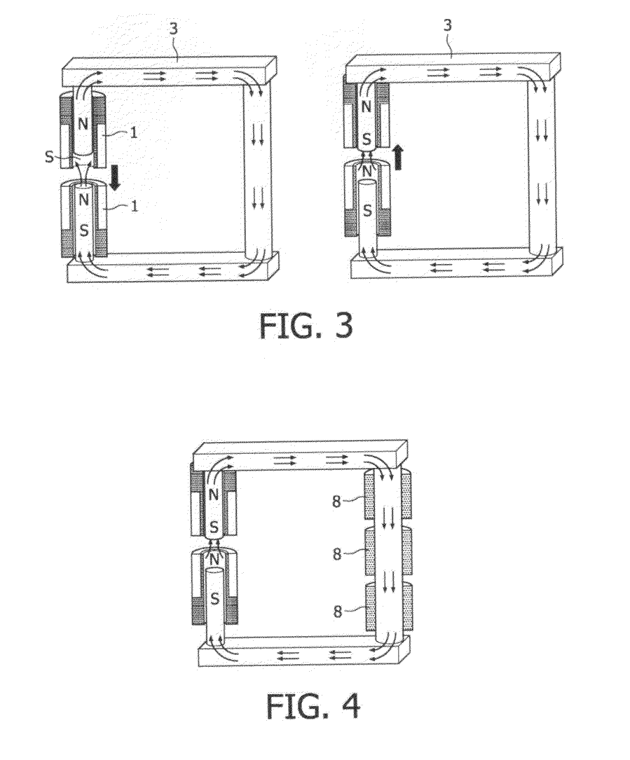

FIG. 2 shows a retarding magnetic system, only in the detailed overview of the magnetic circuit near the magnetic relevant pole surfaces. Retarding system means, that an open magnetic ring system, like shown in FIGS. 3 and 4 has movable or slidable coils 1 or fixed coils and a movable magnetic ring system 6, so that in each case is realized a possible relative movement between magnetic core and coils.

The relevant position of the biosensor is in the gap between the upper and the lower pole surface, like shown in FIG. 2.

Left side shows the magnetic system in a relative position, by which at the upper pole surface occurs effectively a cuplike cylindrical opening 5, during the lower effective pole surface is planar. The effective magnetic force in this relative position is orientated downwards. If the active biosensor surface, located in the gap 4, is orientated upwards, then this position constellation causes a retarded attractive force to the beads of the biomaterial to be analysed, in order to bring it close to the active biosensor surface.

Right side shows the other relative end position of the magnetic system. The coil 1 relatively to the magnetic core, or the core relatively to the coil is shifted in such a way, that the upper pole surface closes planar, during the other pole surface causes the cuplike opening.

This position causes the other desired magnetic force direction, by which the effective magnetic force in the gap is orientated upwards. For the same biosensor position in the gap, it causes a repulsive magnetic force to the magnetic beads, so that the biomaterial is washed from the biosensor surface in order to prepare the biosensor surface for a new measurement.

FIG. 3 shows the complete magnetic ring system in both switched magnetic force positions. So a very quick switch between magnetic attraction and repulsion is possible. The relative positions on the left side and on the right side is equal to the detailed FIG. 2. This FIG. 3 shows now clearly, that the changing planar and cuplike pole surfaces can be caused by shifting the coils 1 relative to the magnetic ring, in the described manner, or to shift the complete ferromagnetic ring 3 relatively to the fixed coils 1.

The last manner is advantageous because this magnetic circuit can be shifted easily, in order to have a quick switch between attractive and repulsive magnetic force in the gap, or better, to the biosensor surface.

In the case of mechanical reversion of the shifting movement, the coils 1 must be coupled together, because the dimension of the effective gap must be kept equal.

FIG. 4 shows a special but very effective, and because of very high effective magnetic forces preferable construction, by which additional coils 8 are positioned in the gapless part of the ferromagnetic ring. By these additional coils, a very high, because retarded magnetic flux will be generated into the ferromagnetic ring, and therefore high magnetic forces in both directions, attraction and repulsion can be generated. The additional coils 8 can be activated, when extraordinary high magnetic forces are desired, in both directions.

The sensor can be any suitable sensor to detect the presence of magnetic particles on or near to a sensor surface, based on any property of the particles, e.g. it can detect via magnetic methods for example. magnetoresistive methods, Hall methods, coils etc., as well as optical methods like imaging, fluorescence, chemiluminescence, absorption, scattering, surface plasmon resonance, Raman, etc. Also sonic detection is possible, that means generation and detection of surface acoustic wave, bulk acoustic wave, cantilever, quartz crystal etc., as well as electrical detection like conduction, impedance, amperometric, redox cycling, etc.

The labels can be detected directly by the sensing method. As well, the particles can be further processed prior to detection. An example of further processing is that materials are added or that the chemical, biochemical or physical properties of the label are modified to facilitate detection.

The detection can occur with or without scanning of the sensor element with respect to the biosensor surface.

In addition to molecular assays, also larger moieties can be detected, e.g. cells, viruses, or fractions of cells or viruses, tissue extract, etc.

Measurement data can be derived as an end-point measurement, as well as by recording signals kinetically or intermittently.

The device and method can be used with several biochemical assay types, e.g. binding/unbinding assay, sandwich assay, competition assay, displacement assay, enzymatic assay, etc.

The device, methods and systems of this invention are suited for sensor multiplexing, for example the parallel use of different sensors and sensor surfaces, label multiplexing for example the parallel use of different types of labels, and chamber multiplexing for example the parallel use of different reaction chambers.

The device, methods and systems described in the present invention can be used as rapid, robust, and easy to use point-of-care biosensors for small sample volumes. The reaction chamber can be a disposable item to be used with a compact reader, containing the one or more magnetic field generating means and one or more detection means. Also, the device, methods and systems of the present invention can be used in automated high-throughput testing. In this case, the reaction chamber is e.g. a well plate or cuvette, fitting into an automated instrument.

The biosensor surface, which is not shown in the figures, but which is defined clearly as positioned inside the gap of the magnetic ring in a centered position can also be optimized in his position by a magnetic flux sensor, in order to effect the best position of high magnetic field density.

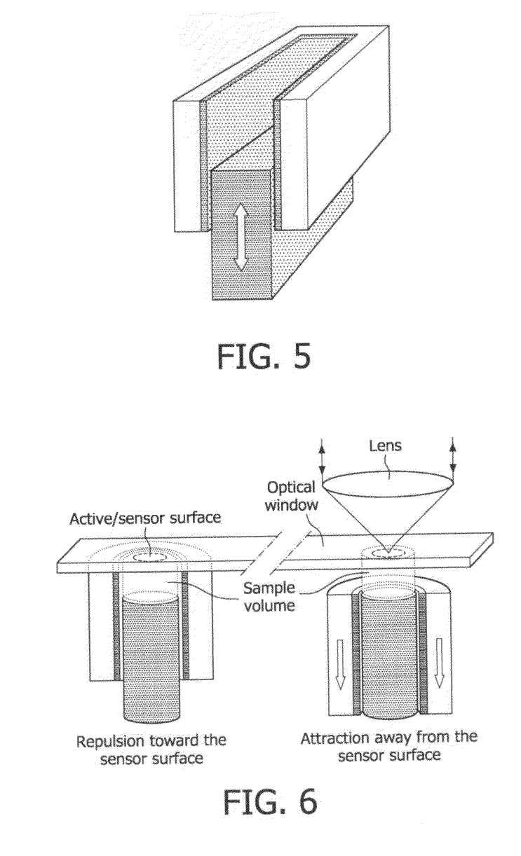

FIG. 5 shows an example of the inventions with another geometry.

This is an extra embodiment, where a possible use of the invention in combination with an optical detection system is given. By this, the cuplike opening in the magnetic core extends to a rectangular cross-section. This makes clear, that the essential feature of the invention is, that the pole shoes contains regions with low magnetic susceptibility. This can also be realised by the geometry in FIG. 5.

FIG. 6 shows optical means for the aforesaid optical or optoelectronical detection. Optical labels offer some desirable properties:

Many detection possibilities like imaging, fluorescence, absorption, scattering, turbidometry, SPR, SERRS, luminescence, chemiluminescence, electrochemiluminescence, FRET, etc.

Imaging possibility offers high multiplexing.

Optical labels are generally small and do not influence the assay too much.

A good combination would be to use magnetic labels that can be actuated by applying magnetic field gradients and that can be detected optically. An advantage is that optics and magnetics are orthogonal in the sense that in most cases optical beams do not show interference with magnetic fields and vice versa. This means that magnetic actuation would be ideally suited for combination with optical detection. Problems such as sensor disturbance by the actuation fields are eliminated.

The problem of combining magnetic actuation and optical detection is in the geometrical constraint. To develop a cartridge technology that is compatible with magnetic actuation means, typically an electromagnet needs to operate at a small distance between magnet and sensor surface. An optical system needs to scan the same surface, possible with high-NA optics. The opto-mechanical set-up and the electromagnet therefore hinder each other when integrating a concept with magnetic actuation and optical detection. Preferably, a configuration with a magnet on only one side is needed. This magnet is able to generate a switchable magnetic field.

1. A magnetic system for biosensors, with at least one coil (1) and a ferromagnetic open ring system (3), where both magnetic pole faces are adjacent to each other over a gap (4) in which the biosensor is located, and where the coil (1) or the ferromagnetic core (2) in the coil, or an inner part of the ferromagnetic core in relation to each other are shiftable, in order to change the magnetic force direction near the biosensor surface.

2. A magnetic system for biosensors according to claim 1, characterized in that the inner part of the ferromagnetic core (2) has a cylindrical coaxial cross-section.

3. A magnetic system for biosensors according to claim 1, characterized in that the inner part of the ferromagnetic core (2) has a squared or rectangular cross-section.

4. A magnetic system for biosensors according to claim 1, characterized in that the coil (1) or the coil carrying means are shiftable along the ferromagnetic sections near the gap (4).

5. A magnetic system for biosensors according to claim 1, characterized in that the ferromagnetic open ring system (3) has at least along the length of the shift of the coils a cylindrical cross section.

6. A magnetic system for biosensors according to claim 4, characterized in that two coils (1) are used, so that each side of the open magnetic ring (3) carries at least one shiftable coil, wherein the two coils are coupled in the movement.

7. A magnetic system for biosensors according to claim 1, characterized in that further coils (8) are arranged immotile in the ferromagnetic ring (3), in order to boost the magnetic forces in the gap (4) of the open ferromagnetic ring.

8. A magnetic system for biosensors according to claim 1, characterized in that the biosensor is adjustable in the position in the gap (4) of the ferromagnetic open ring system (3).

9. A magnetic system for biosensors according to claim 1, characterized in that a magnetic field sensor is located near the biosensor.

10. A magnetic system for biosensors according to claim 1, characterized in that optical means are arranged near the sensor surface in order to make the sensor surface visible or optically analysable with further opto-electronical means.

11. Method for operating a magnetic system with biosensor as described in claim 1, by which a sensing material or liquid is dispersed with or chemically bound to microscopic magnetic beads, and one of the ferromagnetic core or an inner coaxial cylindrical part of the magnetic core, or one of the coil is shifted backwards, in order to generate magnetic repulsion near the sensor surfaces area to wash the surface by repulsion forces of the magnetic beads, then the other ferromagnetic core or an inner coaxial cylindrical part of the magnetic core, or one of the coil is shifted backwards in order to generate attraction forces to the magnetic beads for sensing the bio-substrate in a very close contact to the sensor surface.

12. Method according to claim 11, characterized in that the shifting movement of the coils or the ferromagnetic cores or core pieces relative to each other causes alternatively an effective cylindrical cavity in one or in the other pole surface, in order to switch between repulsive and attractive magnetic force direction.

13. Method according to claim 11, characterized in that a static ferromagnetic ring core with a gap between two pole surfaces is used, and at least two coils are alternatively be shifted in the aforesaid manner, in order to result an effective opening once in one and once in the other ferromagnetic core in relation to its coil.
